(19) United States
(12) Patent Application Publication
(10) Pub. No.: US 2025/0239468 A1
(43) Pub. Date: Jul. 24, 2025

(54) METHOD OF PROCESSING WAFER

(71) Applicant: DISCO CORPORATION, Tokyo (JP)

(72) Inventors: Akira MIZUTANI, Tokyo (JP); Hayato IGA, Tokyo (JP); Shunichiro HIROSAWA, Tokyo (JP)

(21) Appl. No.: 19/016,190

(22) Filed: Jan. 10, 2025

(30) Foreign Application Priority Data
Jan. 22, 2024 (JP) 2024-007269

(51) Int. Cl. H01L 21/67; B23K 26/53; B23K 101/40; H01L 21/02; H01L 21/304; H01L 21/78

(52) U.S. Cl. CPC H01L 21/67092; B23K 26/53; H01L 21/02021; H01L 21/304; H01L 21/78; B23K 2101/40

(57) ABSTRACT

A method of processing a wafer that is bonded as a first wafer to a second wafer in a bonded wafer assembly includes forming a provisionally bonded wafer assembly having the first wafer and the second wafer that are bonded to each other with a relatively weak bonding force, forming a modified layer in the first wafer of the provisionally bonded wafer assembly by applying a laser beam to a region positioned within the first wafer radially inwardly of and adjacent to a chamfered outer circumferential edge of the first wafer, removing the chamfered outer circumferential edge from the first wafer along the modified layer that acts as a removal initiating point, and forming a completely bonded wafer assembly in which the first wafer and the second wafer are bonded to each other with an increased bonding force by annealing the provisionally bonded wafer assembly.

### BACKGROUND OF THE INVENTION

### Field of the Invention

The present invention relates to a method of processing a wafer that is bonded as a first wafer to a second wafer in a bonded wafer assembly.

### Description of the Related Art

Wafers having a plurality of devices such as integrated circuits (ICs) or large-scale integration (LSI) circuits, for example, constructed in respective areas demarcated on their face side by a grid of projected dicing lines are ground on their reverse side to a predetermined thickness. Thereafter, the wafers are divided into individual device chips including the respective devices along the projected dicing lines by a dicing apparatus or a laser processing apparatus. The device chips will be incorporated in various electronic appliances such as cellular phones and personal computers, for example.

Each of the wafers has a chamfered outer circumferential edge. When the reverse side of the wafer is ground, the chamfered outer circumferential edge is turned into a sharp knife edge that is likely to cause various problems. For example, the knife edge tends to develop cracks into the wafer, damaging some of the devices positioned in a central region of the wafer, and is liable to inflict injuries on an operator when the operator handles the wafer. To solve these problems, there has been proposed a technology for removing the chamfered outer circumferential edge from a wafer (see, for example, JP 2020-088187A).

### SUMMARY OF THE INVENTION

However, the proposed technology finds it relatively difficult to remove the chamfered outer circumferential edge from a wafer in a bonded wafer assembly including a first wafer and a second wafer that are bonded to each other for increased device functionality, the first wafer being the wafer from which the chamfered outer circumferential edge is to be removed. The reasons for the difficulty will be described below.

(1) The bonding strength or force of the bonded wafer assembly in which the first wafer and the second wafer are bonded to each other by a siloxane bond is so strong that it is difficult to remove the chamfered outer circumferential edge from the first wafer even if a modified layer is formed in the first wafer by a laser beam having a wavelength transmittable through the first wafer when the laser beam is applied to the first wafer while its focused spot is positioned within the first wafer adjacent to the chamfered outer circumferential edge.

(2) When the modified layer is formed in the first wafer for the removal of the chamfered outer circumferential edge from the first wafer while the first wafer and the second wafer are being held in intimate contact with each other, the laser beam applied to the first wafer to form the modified layer therein is liable to adversely affect the second wafer to the extent that the second wafer may possibly be damaged.

(3) One alternative is to use a cutting blade to cut off the chamfered outer circumferential edge from the first wafer. However, it is difficult for the cutting blade to completely remove the chamfered outer circumferential edge from the first wafer without harming the first wafer.

(4) In a case where a reverse side of the first wafer has surface irregularities or is coated with a film, when efforts are made to form a modified layer in the first wafer with a laser beam, as described above in (1), the laser beam tends to be irregularly reflected or reflected by the reverse side of the first wafer. Therefore, a modified layer may not properly be formed in the first wafer, resulting in a failure to appropriately remove the chamfered outer circumferential edge from the first wafer.

It is an object of the present invention to provide a method of processing a wafer that is bonded as a first wafer to a second wafer in a bonded wafer assembly to properly remove a chamfered outer circumferential edge from the first wafer.

In accordance with an aspect of the present invention, there is provided a method of processing a wafer that is bonded as a first wafer to a second wafer in a bonded wafer assembly, including forming a provisionally bonded wafer assembly having the first wafer and the second wafer that are bonded to each other with a relatively weak bonding force, forming a modified layer in the first wafer of the provisionally bonded wafer assembly by applying a laser beam to a region positioned within the first wafer radially inwardly of and adjacent to a chamfered outer circumferential edge of the first wafer, removing the chamfered outer circumferential edge from the first wafer along the modified layer that acts as a removal initiating point, forming a completely bonded wafer assembly in which the first wafer and the second wafer are bonded to each other with an increased bonding force by annealing the provisionally bonded wafer assembly in which the chamfered outer circumferential edge has been removed from the first wafer, and after removing the chamfered outer circumferential edge and before or after forming the completely bonded wafer assembly, grinding the first wafer to a desired thickness.

Preferably, the method of processing a wafer further includes after forming the provisionally bonded wafer assembly but before forming the modified layer, grinding the first wafer to remove, from the first wafer, a layer tending to obstruct the laser beam applied in forming the modified layer. Preferably, the first wafer and the second wafer are each a silicon wafer, the first wafer and the second wafer of the provisionally bonded wafer assembly are bonded to each other by an Si—OH—OH—Si bond, and the first wafer and the second wafer of the completely bonded wafer assembly are bonded to each other by an Si—O—Si bond.

The method of processing a wafer according to the aspect of the present invention is capable of properly removing the chamfered outer circumferential edge from the first wafer of the bonded wafer assembly that includes the first wafer and the second wafer that are bonded to each other.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is an exploded perspective view illustrating the manner in which a provisionally bonded wafer assembly forming step of a method of processing a wafer according to an embodiment of the present invention is carried out;

FIG. 2 is a perspective view illustrating the manner in which a provisionally bonded wafer assembly is placed on a chuck table of a grinding apparatus;

FIG. 3 is a perspective view illustrating the manner in which a pre-grinding step of the method of processing a wafer is carried out;

FIG. 4A is a perspective view illustrating the manner in which a modified layer forming step of the method of processing a wafer is carried out;

FIG. 4B is an enlarged fragmentary cross-sectional view illustrating the manner in which a modified layer is formed in the modified layer forming step illustrated in FIG. 4A;

FIG. 5 is a plan view of a first wafer that includes radial modified layers formed therein;

FIG. 6 is a perspective view illustrating the manner in which a chamfered outer circumferential edge removing step of the method of processing a wafer is carried out;

FIG. 7 is a perspective view illustrating the manner in which a completely bonded wafer assembly forming step of the method of processing a wafer is carried out;

FIG. 8A is a perspective view illustrating the manner in which a completely bonded wafer assembly is placed on a chuck table in preparation for a finishingly grinding step of the method of processing a wafer is carried out; and

FIG. 8B is a perspective view illustrating the manner in which the finishingly grinding step is carried out.

### DETAILED DESCRIPTION OF THE PREFERRED EMBODIMENT

A method of processing a wafer according to an embodiment of the present invention will be described in detail below with reference to the accompanying drawings.

### (Provisionally Bonded Wafer Assembly Forming Step)

When the method of processing a wafer according to the present embodiment is carried out, a provisionally bonded wafer assembly forming step is initially carried out to form a provisionally bonded wafer assembly including a first wafer and a second wafer that are bonded to each other with a relatively weak bonding force.

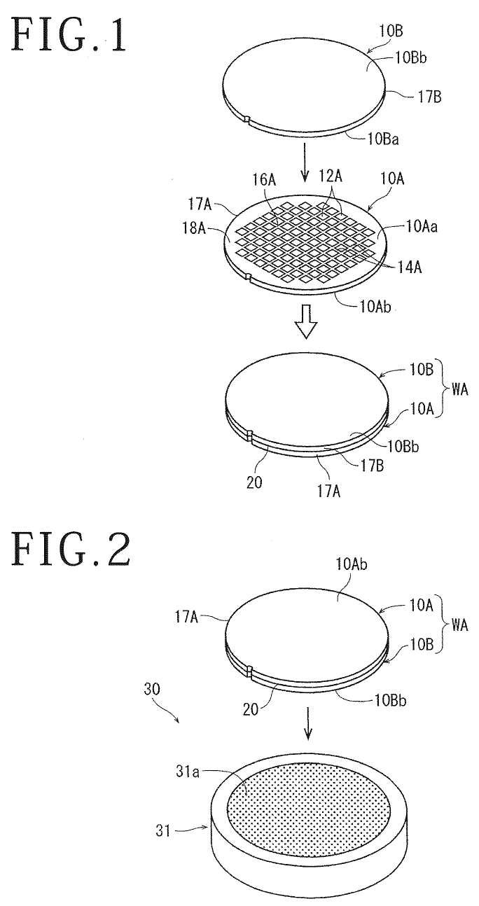

FIG. 1 illustrates in exploded perspective the manner in which the provisionally bonded wafer assembly forming step is carried out. For carrying out the provisionally bonded wafer assembly forming step, a first wafer 10A and a second wafer 10B are prepared. The first wafer 10A is a wafer of silicon (Si) having a diameter of 300 mm and a thickness of 300 μm, for example. A plurality of devices 12A are constructed in respective areas demarcated on a face side 10Aa of the first wafer 10A by a grid of projected dicing lines 14A established thereon. The first wafer 10A has a reverse side 10Ab that faces downwardly in FIG. 1 and that is opposite the face side 10Aa facing upwardly in FIG. 1. The first wafer 10A includes a central effective region 16A where the devices 12A are provided for use as individual products and an outer circumferential excess region 18A surrounding the central effective region 16A. The outer circumferential excess region 18A has a chamfered outer circumferential edge 17A. The second wafer 10B is also a wafer of silicon and is similar in structure to the first wafer 10A. The second wafer 10B also includes a chamfered outer circumferential edge 17B. Although not illustrated, the second wafer 10B has a central effective region where a plurality of devices are constructed in respective areas demarcated on a face side 10Ba facing downwardly in FIG. 1.

In the provisionally bonded wafer assembly forming step, the face side 10Aa of the first wafer 10A and the face side 10Ba of the second wafer 10B are integrally bonded to each other by a hydroxyl group (OH). For example, the face side 10Aa of the first wafer 10A and the face side 10Ba of the second wafer 10B are cleaned in a wet cleaning fashion, forming a hydroxyl group (OH) on them, and then are brought into intimate contact with each other by an Si—OH—OH—Si bond that provides an interface 20 therebetween. The first wafer 10A and the second wafer 10B are thus bonded together into a provisionally bonded wafer assembly WA with a relatively weak bonding force.

### (Modified Layer Forming Step, Pre-Grinding Step)

After the provisionally bonded wafer assembly forming step, a modified layer forming step is carried out to form a modified layer in the first wafer 10A by applying a laser beam to the first wafer 10A while positioning a focused spot thereof in the first wafer 10A radially inwardly of and adjacent to the chamfered outer circumferential edge 17A. In the modified layer forming step, the laser beam is applied to the first wafer 10A from the reverse side 10Ab and has a wavelength transmittable through the first wafer 10A. In a case where the reverse side 10Ab of the first wafer 10A has a layer liable to obstruct a laser beam, such as surface irregularities or a film, e.g., an oxide film, the obstructive layer may possibly disrupt the modified layer forming step. Accordingly, preferably after the provisionally bonded wafer assembly forming step but before the modified layer forming step to be described later, a pre-grinding step is carried out as described below. The pre-grinding step is carried out according to the following sequence.

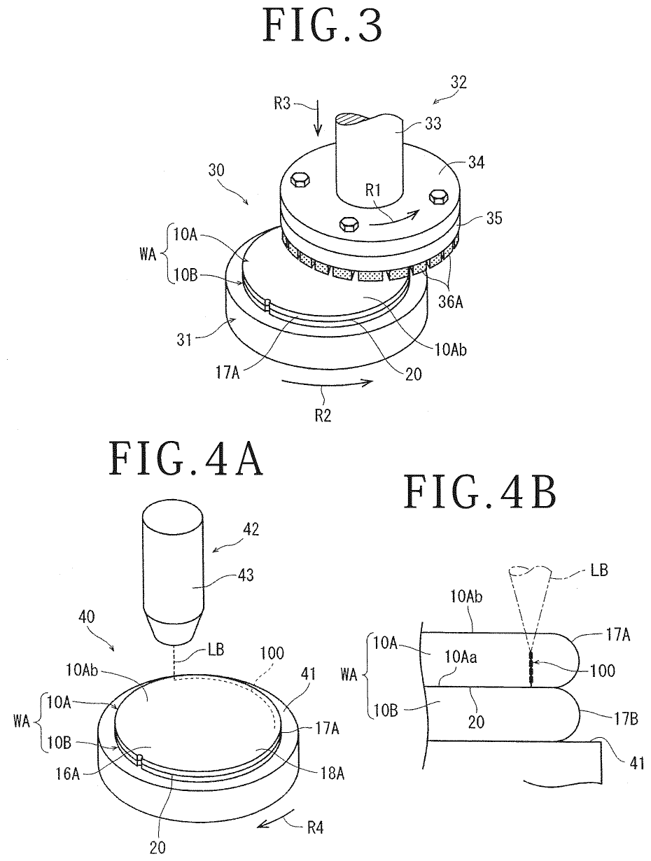

FIG. 2 illustrates in perspective a chuck table 31 of a grinding apparatus 30 that performs the pre-grinding step. FIG. 3 illustrates in perspective a grinding unit 32 for grinding the provisionally bonded wafer assembly WA that is held on the chuck table 31. In FIGS. 2 and 3, only parts of the grinding apparatus 30 are depicted for illustrative purposes. The chuck table 31 includes a suction chuck 31a that is made of an air-permeable porous material and that has an upper surface that provides a holding surface for holding a workpiece, i.e., the provisionally bonded wafer assembly WA, thereon. The chuck table 31 is rotatable about its vertical central axis by an unillustrated rotating mechanism operatively coupled therewith. The chuck table 31 is fluidly connected to unillustrated suction means that, when actuated, generates and transmits a negative pressure to the upper surface of the suction chuck 31a. The grinding unit 32 includes a rotary spindle 33 rotatable about its vertical central axis by an unillustrated rotating mechanism, a wheel mount 34 mounted on the lower end of the rotary spindle 33, and a grinding wheel 35 attached to a lower surface of the wheel mount 34. An annular array of grindstones 36A is disposed on a lower surface of the grinding wheel 35. The grindstones 36A are grinding stones for grinding the reverse side 10Ab of the first wafer 10A to remove an obstructive layer, e.g., surface irregularities or an oxide film, that would otherwise obstruct the laser beam, from the reverse side 10Ab of the first wafer 10A. The grindstones 36A are made of relatively fine abrasive grains. The grinding wheel 35 is vertically movable by an unillustrated grinding feed mechanism operatively coupled with the rotary spindle 33.

The provisionally bonded wafer assembly WA is delivered to the grinding apparatus 30, placed on the suction chuck 31a of the chuck table 31, and held under suction thereon by the negative pressure generated and transmitted by the suction means. Then, the rotary spindle 33 of the grinding unit 32 is rotated about its vertical central axis in a direction indicated by an arrow R1 in FIG. 3 at 6000 rpm, for example, while, at the same time, the chuck table 31 is rotated about its vertical central axis in a direction indicated by an arrow R2 in FIG. 3 at 300 rpm, for example. While an unillustrated grinding water supply unit is supplying grinding water to the reverse side 10Ab of the first wafer 10A of the provisionally bonded wafer assembly WA, the grinding wheel 35 is lowered to bring the grindstones 36A into contact with the reverse side 10Ab of the first wafer 10A and grinding-fed downwardly in a direction indicated by an arrow R3 at a speed of 0.1 μm/s, for example, thereby enabling the grindstones 36A to grind the reverse side 10Ab of the first wafer 10A. During the grinding of the reverse side 10Ab of the first wafer 10A, the thickness of the provisionally bonded wafer assembly WA is measured by a contact-type or contactless-type thickness gauge, which is not illustrated. In this manner, the grindstones 36A grind the reverse side 10Ab of the first wafer 10A by a predetermined thickness to remove the obstructive layer tending to obstruct a laser beam. The thickness of the first wafer 10A that is ground off in the pre-grinding step may be small enough to remove the obstructive layer from the reverse side 10Ab of the first wafer 10A. Therefore, the pre-grinding step is not performed to grind the reverse side 10Ab to the extent that the thickness of the first wafer 10A is substantially thinned down. After the obstructive layer has been removed from the reverse side 10Ab, the grinding unit 32 is shut off, completing the pre-grinding step. If it is determined in advance that the reverse side 10Ab of the first wafer 10A is free of an obstructive layer tending to block a laser beam to be applied to the first wafer 10A from the reverse side 10Ab, then the pre-grinding step may be omitted.

Once the reverse side 10Ab of the first wafer 10A is free of an obstructive layer tending to obstruct a laser beam, the modified layer forming step is carried out as follows.

In preparation for the modified layer forming step, the provisionally bonded wafer assembly WA is delivered to a laser processing apparatus 40 illustrated in FIG. 4A. In FIG. 4A, only parts of the laser processing apparatus 40 are illustrated. As illustrated in FIG. 4A, the laser processing apparatus 40 includes a chuck table 41 for holding the provisionally bonded wafer assembly WA under suction thereon, a laser beam applying unit 42 that includes a beam condenser 43 and applies a laser beam LB, which has a wavelength transmittable through the first wafer 10A, to the first wafer 10A of the provisionally bonded wafer assembly WA on the chuck table 41, an unillustrated moving mechanism for moving the chuck table 41 and the laser beam applying unit 42 relatively to each other, and an unillustrated controller. The chuck table 41 is rotatable about its vertical central axis and is also combined with suction means similar to the suction means fluidly connected to the chuck table 31 illustrated in FIGS. 2 and 3.

The provisionally bonded wafer assembly WA that has been delivered to the laser processing apparatus 40 is placed on the chuck table 41 and held under suction thereon with the first wafer 10A facing upwardly. The provisionally bonded wafer assembly WA on the chuck table 41 is processed in an alignment process by an unillustrated alignment unit on the basis of an image captured of the provisionally bonded wafer assembly WA by the alignment unit. In the alignment process, the controller detects the position of an outer circumferential edge of the provisionally bonded wafer assembly WA that is aligned with the chamfered outer circumferential edge 17A, the position of the center of the provisionally bonded wafer assembly WA, the height of the reverse side 10Ab of the first wafer 10A from the chuck table 41, and a processing position where the laser beam LB is to be applied to the first wafer 10A while its focused spot is being positioned radially inwardly and adjacent to the chamfered outer circumferential edge 17A, or more specifically, a position located radially outwardly of the central effective region 16A and within the outer circumferential excess region 18A, e.g., a position spaced 147 mm radially outwardly from the center of the first wafer 10A. Information representing these positions is stored in the controller.

On the basis of the information representing these positions detected in the alignment process, the moving mechanism is actuated to move the chuck table 41 to place the processing position directly below the beam condenser 43 of the laser beam applying unit 42, as illustrated in FIG. 4A. Then, as illustrated in FIG. 4B as well as FIG. 4A, the laser beam LB is applied to the reverse side 10Ab of the first wafer 10A while its focused spot is positioned within the first wafer 10A beneath the processing position, and the rotating mechanism is actuated to rotate the chuck table 41 about its vertical central axis in a direction indicated by an arrow R4 in FIG. 4A, thereby forming a ring-shaped modified layer 100 in the first wafer 10A radially inwardly of and adjacent to the chamfered outer circumferential edge 17A thereof, as illustrated in FIG. 4B.

The modified layer 100 formed in the modified layer forming step should preferably be made up of a vertical array of constituent layers, as illustrated in FIG. 4B. For example, the modified layer 100 illustrated in FIG. 4B is made up of a vertical array of four constituent layers. For forming the modified layer 100 made up of such a vertical array of four layers, first, the laser beam LB is applied to the first wafer 10A while its focused spot is being positioned in the first wafer 10A at a deepest area close to the interface 20, e.g., at a depth of 180 μm from the reverse side 10Ab, radially inwardly of and adjacent to the chamfered outer circumferential edge 17A, and at the same time, the chuck table 41 is rotated about its vertical central axis, thereby forming a ring-shaped constituent modified layer along the chamfered outer circumferential edge 17A. Thereafter, while the chuck table 41 is being rotated about its vertical central axis, the focused spot of the laser beam LB is lifted successively in three steps toward the reverse side 10Ab, e.g., from the depth of 180 μm to a depth of 170 μm, then from the depth of 170 μm to a depth of 160 μm, and finally from the depth of 160 μm to a depth of 150 μm, during which time the focused spot is kept at each of the depths until the chuck table 41 makes at least one revolution about its vertical central axis. As a result, a total of four ring-shaped constituent modified layers are formed in the first wafer 10A adjacent to and along the chamfered outer circumferential edge 17A. In FIG. 4B, the modified layer 100 is conceptually illustrated for illustrative purposes, and the depthwise positions of its four layers are not in accord with their actual dimensions. The modified layer forming step is now completed. The constituent layers of the modified layer 100 formed in the modified layer forming step not limited to four layers. The number of constituent layers of the modified layer 100 is selected depending on the material of the first wafer 10A, the thickness of the first wafer 10A, and the wavelength and power output of the laser beam LB applied to the first wafer 10A by the laser beam applying unit 42, among others.

Laser processing conditions for carrying out the modified layer forming step are established as follows, for example:
Wavelength: 1099 nm
Repetitive frequency: 80 kHz
Average power output: 2.0 W
Processing feed speed: 450 mm/s
or
Wavelength: 1342 nm
Repetitive frequency: 90 kHz
Average power output: 1.9 W
Processing feed speed: 400 mm/s

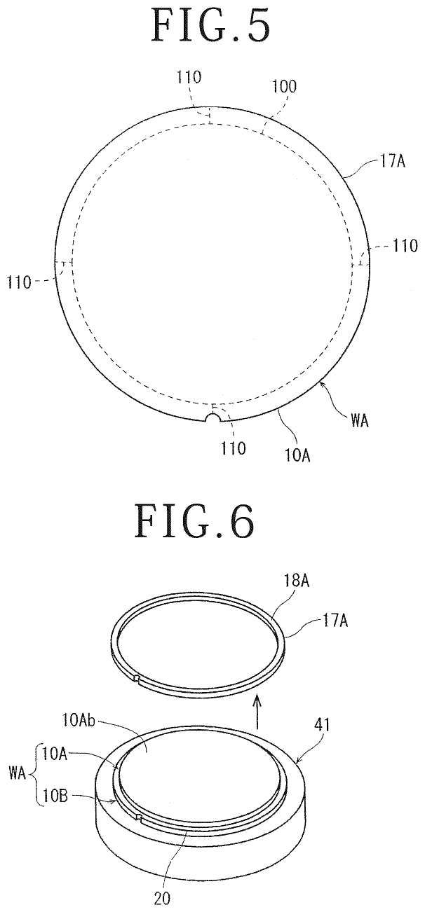

In the modified layer forming step, as illustrated in FIG. 5, a plurality of radial modified layers 110 extending from the region where the modified layer 100 is formed radially outwardly toward the chamfered outer circumferential edge 17A may be additionally formed in the first wafer 10A. The modified layers 110 function to divide the chamfered outer circumferential edge 17A into smaller fragments at the time when the chamfered outer circumferential edge 17A is removed. The modified layers 110 may be formed by the application of the laser beam LB to the first wafer 10A under the same laser processing conditions for forming the modified layer 100. The modified layers 110 may be formed respectively in a plurality of locations, e.g., four locations in the present embodiment, that are angularly spaced at equal angular intervals along the outer circumferential portion of the first wafer 10A. At the time of removing the chamfered outer circumferential edge 17A in a chamfered outer circumferential edge removing step to be described below, the modified layers 110 divide the chamfered outer circumferential edge 17A into smaller fragments, allowing the chamfered outer circumferential edge 17A to be removed easily and effectively from the first wafer 10A.

### (Beveled Outer Circumferential Edge Removing Step)

After the modified layer forming step, the chamfered outer circumferential edge removing step is carried out to remove the chamfered outer circumferential edge 17A from the first wafer 10A, as illustrated in FIG. 6. As described above, the modified layer forming step has been carried out on the provisionally bonded wafer assembly WA where the bonding force of the interface 20 between the first wafer 10A and the second wafer 10B is relatively weak. Therefore, the outer circumferential excess region 18A including the chamfered outer circumferential edge 17A can easily be dislodged and removed from the first wafer 10A along the modified layer 100 acting as a removal initiating point. Any methods available in the art may be applied to carry out the chamfered outer circumferential edge removing step. For example, fluid such as air may be ejected toward the interface 20 from a position sideways of the chuck table 41, or a thin blade may be inserted laterally into the interface 21 to apply an external force to the interface 20 for thereby dislodging and removing the chamfered outer circumferential edge 17A. If the radial modified layers 110 have been formed in the first wafer 10A, then the chamfered outer circumferential edge 17A is removed as fragments in the chamfered outer circumferential edge removing step.

### (Completely Bonded Wafer Assembly Forming Step, Finishingly Grinding Step)

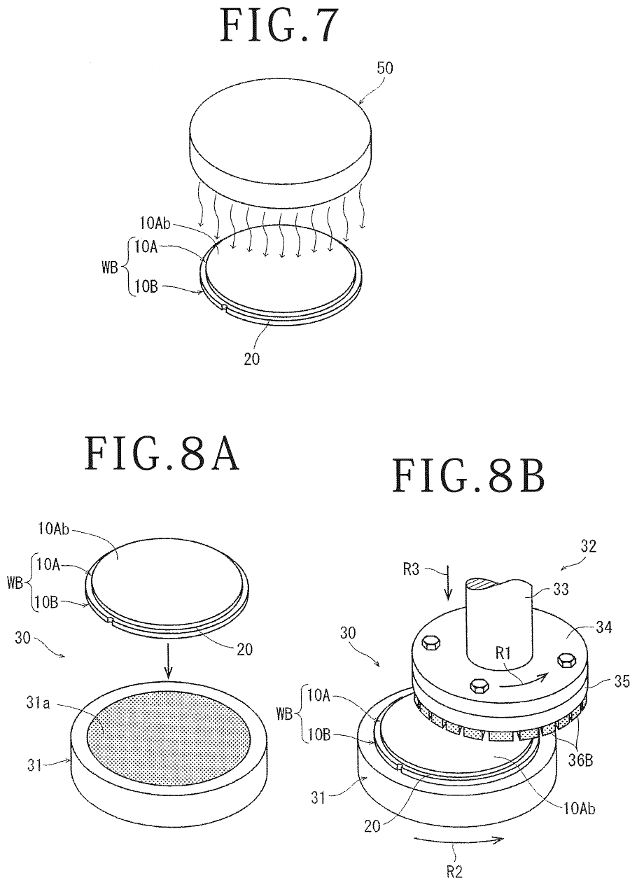

After the chamfered outer circumferential edge removing step has been carried out, a completely bonded wafer assembly forming step is carried out to form a completely bonded wafer assembly WB (see FIG. 7) where the bonding force of the interface 20 is increased by annealing the provisionally bonded wafer assembly WA in which the chamfered outer circumferential edge 17A has been removed from the first wafer 10A, and before or after the completely bonded wafer assembly forming step, a finishingly grinding step is carried out to finishingly grind the first wafer 10A to a desired thickness. According to the present embodiment to be described below, the completely bonded wafer assembly forming step is carried out before the finishingly grinding step. However, the finishingly grinding step may be carried out before the completely bonded wafer assembly forming step.

For carrying out the completely bonded wafer assembly forming step, the provisionally bonded wafer assembly WA in which the chamfered outer circumferential edge 17A has been removed from the first wafer 10A in the chamfered outer circumferential edge removing step is introduced into an unillustrated heating chamber that incorporates a heater 50 illustrated in FIG. 7. The provisionally bonded wafer assembly WA introduced into the heating chamber is then heated by the heater 50. The heater 50 may be an infrared heater, for example, for heating the provisionally bonded wafer assembly WA with radiant heat. In the completely bonded wafer assembly forming step, the heater 50 heats the provisionally bonded wafer assembly WA at a predetermined temperature of approximately 1000° C. for a certain period of time, thereby performing an annealing process on the provisionally bonded wafer assembly WA to change the relatively weak Si—OH—OH—Si bond based on the hydroxyl group (OH) of the interface 20 between the first wafer 10A and the second wafer 10B into an Si—O—Si bond, i.e., a siloxane bond, that firmly bonds the first wafer 10A and the second wafer 10B to each other. The provisionally bonded wafer assembly WA is now turned into the completely bonded wafer assembly WB. The completely bonded wafer assembly forming step is completed.

After completely bonded wafer assembly forming step, the completely bonded wafer assembly WB is delivered to a grinding apparatus 30 illustrated in FIGS. 8A and 8B that carries out the finishingly grinding step to grind the first wafer 10A to a desired thickness. The grinding apparatus 30 illustrated in FIGS. 8A and 8B is similar to the grinding apparatus 30 illustrated in FIG. 3 except that it performs first grinding and then second grinding on the first wafer 10A. In the first grinding, the grinding wheel 35 on which an annular array of grindstones 36B made of coarse abrasive grains is disposed is attached to the wheel mount 34, and the reverse side 10Ab of the first wafer 10A is ground by the grindstones 36B. In the second grinding, the grinding wheel 35 on which the annular array of grindstones 36A (see FIG. 3) made of fine abrasive grains are disposed is attached to the wheel mount 34, and the reverse side 10Ab of the first wafer 10A is ground by the grindstones 36A. In the first grinding and the second grinding, the reverse side 10Ab of the first wafer 10A is ground to finish the completely bonded wafer assembly WB to the desired thickness.

Specifically, the completely bonded wafer assembly WB is delivered to the grinding apparatus 30 illustrated in FIG. 8A, placed on the suction chuck 31a of the chuck table 31 with the reverse side 10Ab of the first wafer 10A facing upwardly, and held under suction thereon by the negative pressure generated and transmitted by the suction means. In the finishingly grinding step according to the present embodiment, the thickness of the first wafer 10A that is 300 μm thick is thinned down to a desired thickness, e.g., 100 μm. More specifically, the grinding wheel 35 with the coarse grindstones 36B disposed thereon is attached to the wheel mount 34. Then, the rotary spindle 33 of the grinding unit 32 is rotated about its vertical central axis in the direction indicated by the arrow R1 in FIG. 8B at 6000 rpm, for example, while, at the same time, the chuck table 31 is rotated about its vertical central axis in the direction indicated by the arrow R2 in FIG. 8B at 300 rpm, for example. While the unillustrated grinding water supply unit is supplying grinding water to the reverse side 10Ab of the first wafer 10A, the grinding wheel 35 is lowered to bring the grindstones 36B into contact with the reverse side 10Ab of the first wafer 10A and grinding-fed downwardly in the direction indicated by the arrow R3 in FIG. 8B at a speed of 0.1 μm/s, for example, thereby enabling the grindstones 36B to grind the reverse side 10Ab of the first wafer 10A by a depth of 170 μm (first grinding). During the grinding of the reverse side 10Ab of the first wafer 10A, the thickness of the completely bonded wafer assembly WB is measured by a contact-type or contactless-type thickness gauge, which is not illustrated.

Then, the grinding wheel 35 with the coarse grindstones 36B disposed thereon is replaced with the grinding wheel 35 with the fine grindstones 36A disposed thereon, and the second grinding is performed in the same manner as with the first grinding to grind the reverse side 10Ab of the first wafer 10A by a depth of 30 μm, so that the first wafer 10A is ground to the desired thickness of 100 μm. In this manner, the reverse side 10Ab of the first wafer 10A is finished to a smoother surface. In the finishingly grinding step, both the first grinding and the second grinding may not necessarily be carried out, and either one of them may be carried out as required. When the finishingly grinding step has been carried out, the method of processing a wafer according to the present embodiment comes to an end.

According to the present embodiment, since the chamfered outer circumferential edge removing step for removing the chamfered outer circumferential edge 17A from the first wafer 10A is carried out on the provisionally bonded wafer assembly WA in which the first wafer 10A and the second wafer 10B are bonded to each other by the relatively weak bonding force, the chamfered outer circumferential edge 17A can easily be dislodged and removed from the first wafer 10A. Consequently, the problem (1) referred to above is solved. Moreover, the modified layer forming step is carried out on the provisionally bonded wafer assembly WA to form the modified layer 100 in the first wafer 10A. Therefore, the laser beam LB is applied to the first wafer 10A from the reverse side 10Ab while the first wafer 10A and the second wafer 10B are not being held in intimate contact with each other and minuscule gaps are being present therebetween, the laser beam LB is obstructed or interrupted by the minuscule gaps. The problem (2) of the laser beam LB reaching and damaging the second wafer 10B is thus solved.

In addition, in a case where the reverse side 10Ab of the first wafer 10A has an obstructive layer such as surface irregularities or a film that tends to obstruct the laser beam LB from the first wafer 10A, the pre-grinding step carried out on the provisionally bonded wafer assembly WA removes the obstructive layer. Therefore, the modified layer 100 can properly be formed in the first wafer 10A by the laser beam LB applied thereto in the modified layer forming step. In this manner, the problem (4) is solved. Further, inasmuch as it is not necessary to use a cutting blade to remove the chamfered outer circumferential edge 17A from the first wafer 10A, the problem (3) is also solved.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A method of processing a wafer that is bonded as a first wafer to a second wafer in a bonded wafer assembly, comprising:
forming a provisionally bonded wafer assembly having the first wafer and the second wafer that are bonded to each other with a relatively weak bonding force;
forming a modified layer in the first wafer of the provisionally bonded wafer assembly by applying a laser beam to a region positioned within the first wafer radially inwardly of and adjacent to a chamfered outer circumferential edge of the first wafer;
removing the chamfered outer circumferential edge from the first wafer along the modified layer that acts as a removal initiating point;
forming a completely bonded wafer assembly in which the first wafer and the second wafer are bonded to each other with an increased bonding force by annealing the provisionally bonded wafer assembly in which the chamfered outer circumferential edge has been removed from the first wafer; and
after removing the chamfered outer circumferential edge and before or after forming the completely bonded wafer assembly, grinding the first wafer to a desired thickness.

2. The method of processing a wafer according to claim 1, further comprising:
after forming the provisionally bonded wafer assembly but before forming the modified layer, grinding the first wafer to remove, from the first wafer, a layer tending to obstruct the laser beam applied in forming the modified layer.

3. The method of processing a wafer according to claim 1,
wherein the first wafer and the second wafer are each a silicon wafer,
the first wafer and the second wafer of the provisionally bonded wafer assembly are bonded to each other by an Si—OH—OH—Si bond, and
the first wafer and the second wafer of the completely bonded wafer assembly are bonded to each other by an Si—O—Si bond.
